(19) United States
(12) Patent Application Publication
(10) Pub. No.: US 2025/0324571 A1
(43) Pub. Date: Oct. 16, 2025

(54) SEMICONDUCTOR DEVICE AND METHOD OF FORMING THE SAME

(71) Applicant: Winbond Electronics Corp., Taichung City (TW)

(72) Inventor: Yi-Chi TSAI, Tainan City (TW)

(21) Appl. No.: 18/825,050

(22) Filed: Sep. 5, 2024

(30) Foreign Application Priority Data
Apr. 15, 2024 (TW) 113113944

(51) Int. Cl. H10B 12/00

(52) U.S. Cl. CPC H10B 12/34; H10B 12/053

(57) ABSTRACT

A semiconductor device and a method of forming the same are provided. The semiconductor device includes a substrate, a word line structure, a gate conductive layer, a contact, and a liner. The word line structure is disposed in the substrate. The gate conductive layer is disposed on the word line structure. The contact is disposed on the word line structure. The liner is disposed between the gate conductive layer and the contact and covers the side surface of the gate conductive layer.

### CROSS REFERENCE TO RELATED APPLICATIONS

This Application claims priority of Taiwan Patent Application No. 113113944, filed on Apr. 15, 2024, the entirety of which is incorporated by reference herein.

### TECHNICAL FIELD

The present invention relates to a semiconductor device and a manufacturing method. Especially for the liner of semiconductor device and forming the same.

### BACKGROUND

Dynamic random access memory (DRAM) has the advantage of fast access speed, as semiconductor devices are miniaturized, memory sizes continue to shrink accordingly to increase integration and improve performance. However, continuous size reductions may result in seams appearance in the contacts that will degrade the performance of the memory.

Although existing semiconductor devices and methods of forming the same gradually meet their intended uses, they are still not fully compliant in all respects. Therefore, there are still some problems to be overcome regarding semiconductor devices and methods of forming the same.

### SUMMARY

The semiconductor device includes a substrate, a word line structure, a gate conductive layer, a contact, and a liner. The word line structure is disposed in the substrate. The gate conductive layer is disposed on the word line structure. The contact is disposed on the word line structure. The liner is disposed between the gate conductive layer and the contact and covers the side surface of the gate conductive layer.

A method of forming a semiconductor device includes providing a substrate. A word line structure is formed in the substrate. A gate conductive layer is formed on the word line structure. A trench is formed in the gate conductive layer, the word line structure, and the substrate. A liner is formed in the trench, so that the liner covers a side surface of the gate conductive layer. A contact is formed in the trench.

### BRIEF DESCRIPTION OF THE DRAWINGS

FIGS. 1 to 19 are schematic cross-sectional views illustrating formation method of a semiconductor device at various stages according to some embodiments of the present disclosure, respectively.

### DETAILED DESCRIPTION

As shown in FIG. 1, a substrate 100 may be provided, the substrate 100 may be, for example, a wafer, a semiconductor on insulator (SOI) substrate, or a bulk semiconductor substrate, the substrate 100 may be a multilayer substrate or a gradient substrate. The substrate 100 may be an element semiconductor, including silicon and germanium; a compound semiconductor, including: silicon carbide, gallium arsenide, gallium phosphide, indium phosphide, indium arsenide, and/or indium antimonide; and an alloy semiconductor, including: SiGe, GaAsP, AlInAs, AlGaAs, GaInAs, GaInP, and/or GaInAsP, or a combination thereof, but the present disclosure is not limited thereto. The substrate 100 may be a doped or undoped semiconductor substrate.

As shown in FIG. 1, an isolation structure STI may be formed in the substrate 100, and the active areas of the semiconductor device are defined by the isolation structure STI. The isolation structure STI may include multiple dielectric layers. For example, the multilayer dielectric layer may include a dielectric layer 101 and a dielectric layer 102 disposed on the dielectric layer 101. The dielectric layer may include an oxide such as silicon oxide, a nitride such as silicon nitride, an oxynitride such as silicon oxynitride, the like, or a combination thereof, but the present disclosure is not limited thereto.

As shown in FIG. 1, a word line structure WLS may be formed in the substrate 100, and the word line structure WLS may be disposed between adjacent isolation structures STI, the word line structure WLS may be a buried word line structure. The word line structure WLS may include a first dielectric layer 103 disposed in the substrate 100, a word line conductive structure disposed on the first dielectric layer 103, and a second dielectric layer 108 disposed on the word line conductive structure. The first dielectric layer 103 may serve as a gate dielectric layer for the word lines. The first dielectric layer 103 and the second dielectric layer 108 may surround the word line conductive structure. The materials and formation methods of the first dielectric layer 103 and the second dielectric layer 108 may be the same or different from the material and formation methods of the dielectric layer 101 and the dielectric layer 102. The first dielectric layer 103 may include silicon oxide, and the second dielectric layer 108 may include silicon nitride.

The word line conductive structure may include a first word line liner 104, a first word line conductive layer 105, a second word line liner 106, and a second word line conductive layer 107, the first word line liner 104 and the second word line liner 106 may improve interface compatibility. The first word line liner 104 may be disposed on the first dielectric layer 103. The first word line conductive layer 105 may be disposed on the first word line liner 104. The second word line liner 106 may be disposed on the first word line liner 104 and the first word line conductive layer 105. The second word line conductive layer 107 may be disposed on the second word line liner 106. The second dielectric layer 108 may be disposed on the second word line conductive layer 107.

The first word line liner 104 and the second word line liner 106 may include TiN, WSi, the like, or a combination thereof, but the present disclosure is not limited thereto, the first word line conductive layer 105 and the second word line conductive layer 107 may include a conductive material. For example, the conductive material may include polysilicon; amorphous silicon; a metal such as tungsten, copper, silver, gold, cobalt; a metal nitride such as tungsten nitride, titanium nitride; a conductive metal oxide; another suitable material, or a combination thereof. The first word line conductive layer 105 may include tungsten, and the second word line conductive layer 107 may include polysilicon. The first word line liner 104, the first word line conductive layer 105, the second word line liner 106, and the second word line conductive layer 107 may be formed by a deposition process such as a chemical vapor deposition process, a sputtering process, the like, or a combination thereof.

As shown in FIG. 1, a mask 109 and a mask 110 may be formed on the word line structure WLS and the isolation structure STI, the mask 109 may include silicon nitride and the mask 110 may include silicon oxide. The mask 109 and the mask 110 may be omitted.

As shown in FIG. 1, a gate conductive layer 200 may be formed on the word line structure WLS and the isolation structure STI, the gate conductive layer 200 may be disposed on the mask 110. If the mask 109 and the mask 110 are omitted, the gate conductive layer 200 may be disposed on the second dielectric layer 108 of the word line structure WLS. The material and formation method of the gate conductive layer 200 may be the same as or different from the materials and formation methods of the first word line conductive layer 105 and the second word line conductive layer 107. The gate conductive layer 200 may include polysilicon.

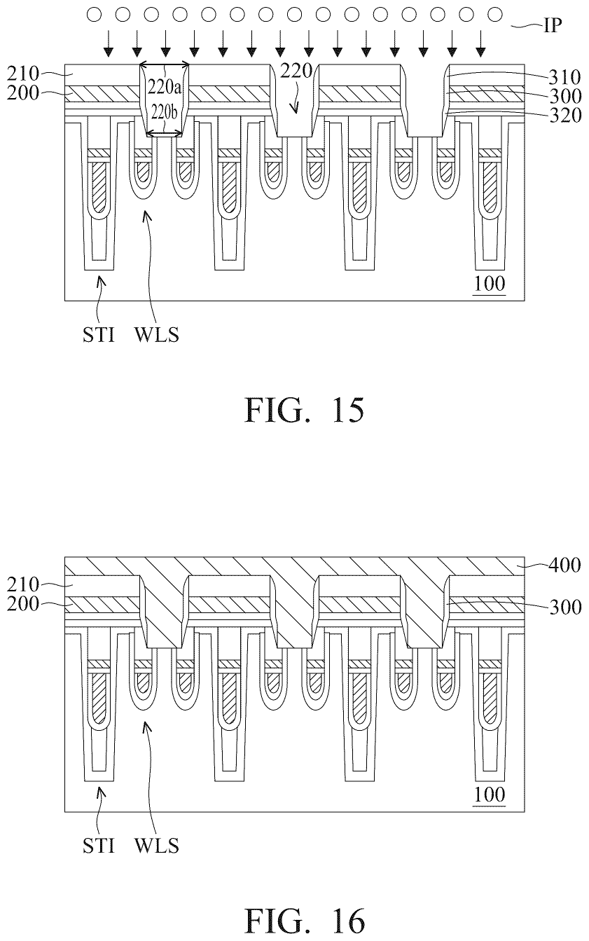

As shown in FIG. 1, a patterned mask 210 may be formed on the gate conductive layer 200. Next, a removal process such as an etching process is performed on the gate conductive layer 200. For example, the patterned mask 210 is used as an etching mask, and a dry etching process is used to etch the gate conductive layer 200 to pattern the gate conductive layer 200, thereby forming a trench 220 in the gate conductive layer 200, the mask 110, the mask 109, the word line structure WLS, and the substrate 100, the trench 220 may penetrate the gate conductive layer 200 and not penetrate the word line structure WLS and the substrate 100, in order to expose the side surface 200S of the gate conductive layer 200, the top surface of the word line structure WLS, and the top surface of the substrate 100. The shape of the trench 220 may be controlled by adjusting the parameters of the etching process. For example, when viewed in a cross-sectional view, the trench 220 may have a rectangular profile, but the present disclosure is not limited thereto. The upper width 220a of the trench 220 away from the substrate 100 and the bottom width 220b of the trench 220 adjacent to the substrate 100 may be substantially the same (refer to FIG. 1). For example, when viewed in a cross-sectional view, the trench 220 may have a pentagonal profile. The upper width 220a of the trench 220 may be greater than the bottom width 220b of the trench 220 (refer to subsequent FIGS. 8 and 15).

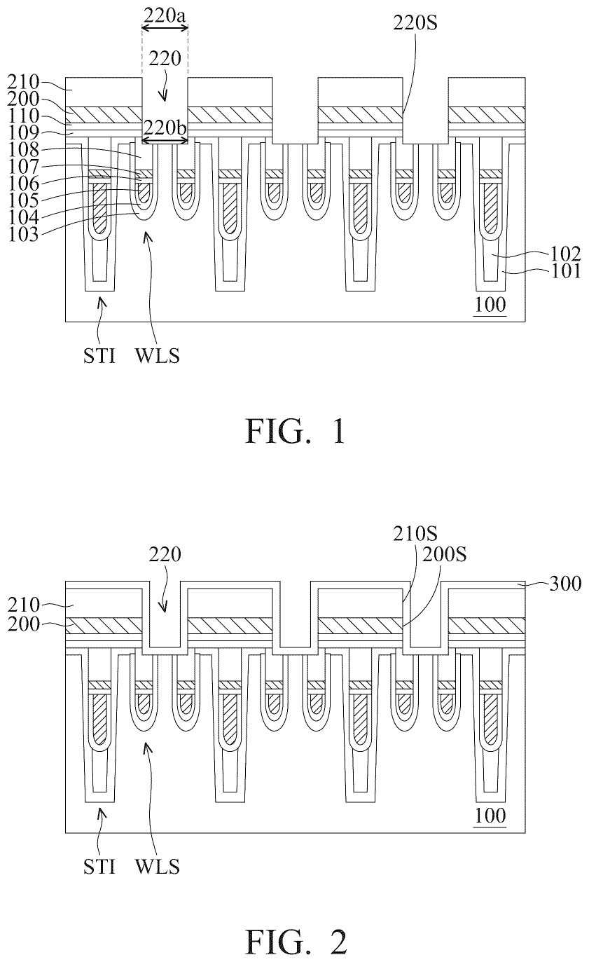

As shown in FIG. 2, a liner 300 is conformally formed in trench 220, the liner 300 may be disposed on the top and side surfaces of the mask 210, the side surface 200S of the gate conductive layer 200, the top surface of the word line structure WLS, and the top surface of the substrate 100, the liner 300 may be in contact with the first dielectric layer 103 and the second dielectric layer 108 of the word line structure WLS. The material and formation method of the liner 300 may be the same as or different from the materials and formation methods of the dielectric layer 101 and the dielectric layer 102. The liner 300 may include silicon oxide or silicon nitride. In a normal direction of the substrate 100, the liner 300 may have a thickness greater than or equal to 1 nm and less than or equal to 30 nm. For example, the thickness of the liner 300 may be 1 nm, 3 nm, 5 nm, 10 nm, 20 nm, 30 nm, or any value or any range of values between the aforementioned values, but the present disclosure is not limited thereto.

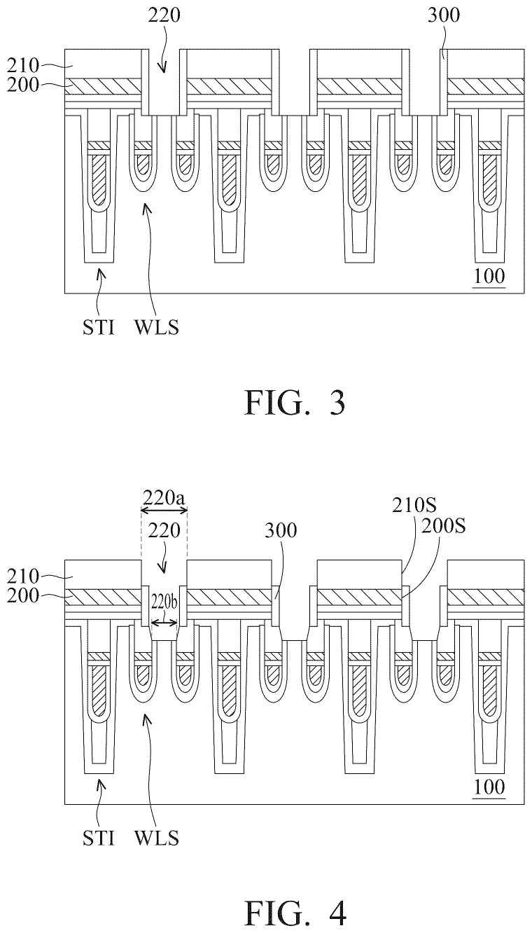

As shown in FIG. 3, a portion of the liner 300 is removed to expose the top surface of the substrate 100, the horizontal portion of the liner 300 is removed to expose the top surface of the mask 210 and the top surface of the substrate 100. A portion of the liner 300 may be removed by an etching process such as dry etching.

As shown in FIG. 4, the liner 300 is etched back to remove the vertical portion of the liner 300. In the normal direction of the substrate 100, the top surface of the liner 300 may be higher than or aligned (coplanar) with the top surface of the gate conductive layer 200. For example, the liner 300 may cover at least the side surface 200S of the gate conductive layer 200. The liner 300 may further cover a portion of the side surface of the mask 210 to improve the process adjustability (for example, a fault tolerance) of the etch back process. The liner 300 may expose the side surface of the mask 210 to improve the process adjustability of subsequent planarization processes, the liner 300 may be etched back by an etching process such as dry etching. As shown in FIG. 4, etching back of the liner 300 may further remove a portion of the word line structure WLS and a portion of the substrate 100, so that the trench 220 extends toward the substrate 100. After the removal of the portion of the word line structure WLS and the portion of the substrate 100, the upper width 220a of the trench 220 is greater than the bottom width 220b of the trench 220. Accordingly, after the removal of the horizontal portion of the liner 300, the etching back process is performed to extend the depth of the trench 220, which is beneficial to removing the horizontal portion of the liner 300. For example, before performing the etching back process, because the trench 220 may have a rectangular profile, the horizontal portion of the liner 300 may be more susceptible to removal by the dry etching process.

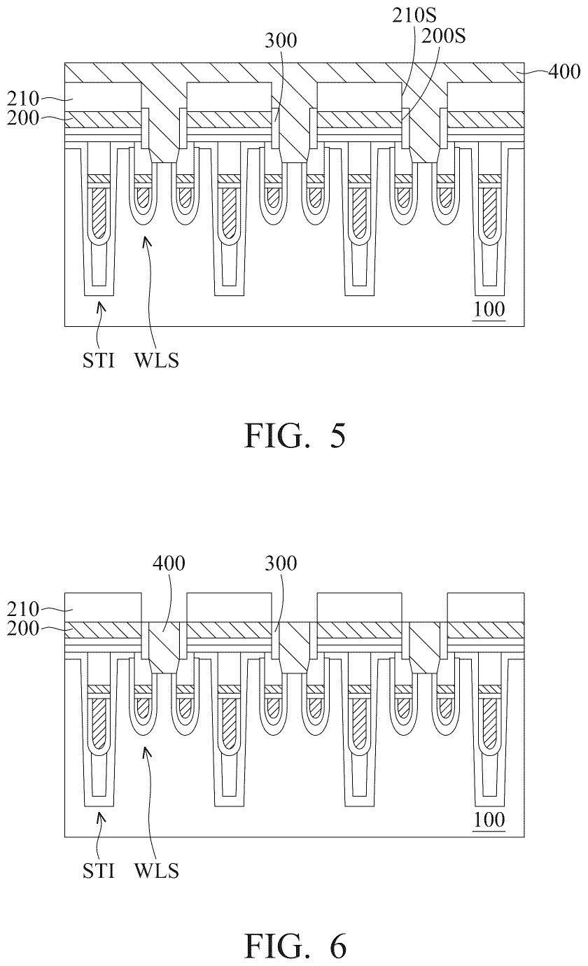

As shown in FIG. 5, a contact material 400 is filled in the trench 220 (refer to FIG. 4), the contact material 400 is deposited in the trench 220. The material and formation method of the contact material 400 may be the same as or different from the material and formation method of the gate conductive layer 200. The contact material 400 may include polysilicon. Accordingly, since the liner 300 may cover the side surface 200S of the gate conductive layer 200, seams in subsequently formed contact may be avoided. For example, when the materials of the gate conductive layer 200 and the contact material 400 are the same or similar (for example, the gate conductive layer 200 and the contact material 400 may include silicon-based materials such as polysilicon), the contact material 400 is trend to be formed (for example, deposited or epitaxial growth) on the side surface 200S of the gate conductive layer 200 rather than on the second dielectric layer 108, the mask 109, or the mask 110. That is, the formation rate of the contact material 400 on the side surface 200S of the gate conductive layer 200 is greater than the formation rate of the contact material 400 on the second dielectric layer 108, the mask 109, or the mask 110. As a result, the overhang of the contact material 400 is produced on the side surface 200S of the gate conductive layer 200. Therefore, the contact material 400 is prone to premature sealing at the side surface 200S of the gate conductive layer 200 so as to form a seam in the contact material 400 located in the trench 220.

In other words, the factor that affects the formation rate of the contact material 400 is that the gate conductive layer 200 includes a similar material to the contact material 400. Therefore, the gate conductive layer 200 may be covered by the liner 300 to prevent the gate conductive layer 200 from affecting the formation rate of contact material 400. Therefore, the liner 300 of the present disclosure may reduce seams in the contacts, thereby improving the electrical performance (for example, reducing the resistance of the contacts to increase current) and reliability of the semiconductor device.

As shown in FIG. 6, the contact material 400 is etched back so that the top surface of the contact material 400 is aligned (coplanar) with the top surface of the liner 300. Accordingly, the process adjustability for subsequent planarization processes may be improved. For example, the planarization process is easier to perform and/or the flatness of the surface after the planarization process is increased.

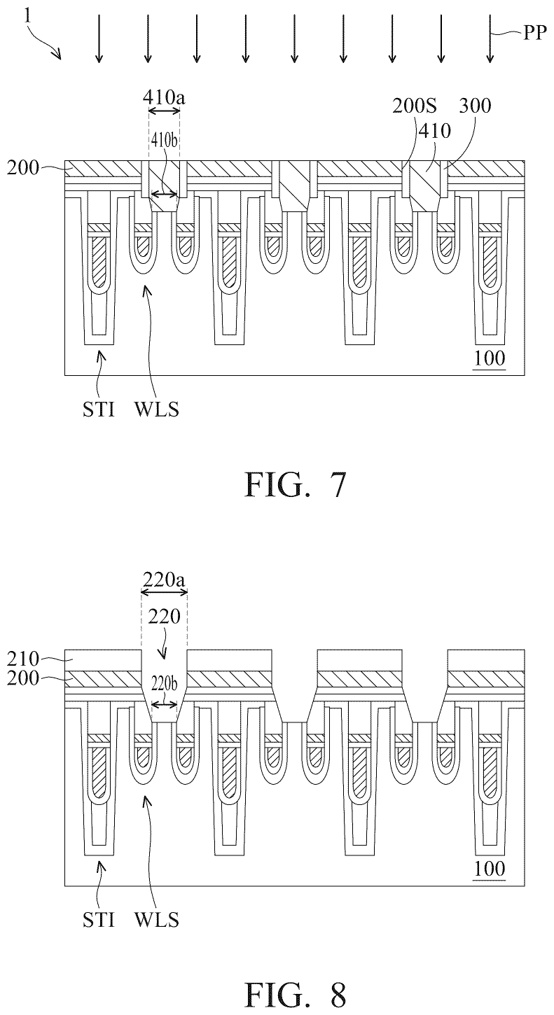

As shown in FIG. 7, a planarization process PP is performed to make the top surface of the gate conductive layer 200, the top surface of the contact material 400 (refer to FIG. 6), and the top surface of the liner 300 coplanar, in order to form the contact 410 in the trench 220 (refer to FIG. 4). Thus, the semiconductor device 1 is obtained, the planarization process PP may include a chemical mechanical polishing (CMP) process or a wet removal process. For example, the wet removal process may use tetrahydrofuran (THF). The contact 410 may be disposed on the word line structure WLS, and the contact 410 may be in contact with the substrate 100. The contact 410 is in contact with the first dielectric layer 103 and the second dielectric layer 108 of the word line structure WLS. The top surface of the gate conductive layer 200, the top surface of the contact 410, and the top surface of the liner 300 may be coplanar. The upper width 410a of the contact 410 away from the substrate 100 may be greater than the bottom width 410b of the contact 410 adjacent to the substrate 100 to improve the process adjustability of subsequent formation of the bit line structure on the contact 410.

Accordingly, since the liner 300 may be disposed between the gate conductive layer 200 and the contact 410, and the liner 300 may cover the side surface 200S of the gate conductive layer 200, it is possible to reduce seams in the contact 410 as described above. In addition, the capacitance in the semiconductor device 1 may be further reduced. For example, further processes may be performed on the semiconductor device 1 to form a dynamic random access memory.

A bit line stack including a bit line conductive structure may be formed on the contact 410 in the semiconductor device 1, and then the bit line stack and the contact 410 are patterned to obtain the bit line structure. The bit line structure may be used as a bit line (or a portion thereof) of the dynamic random access memory. Then, a bit line spacer is further formed on the sidewall of the bit line structure. Since the liner 300 is disposed between the gate conductive layer 200 and the contact 410, the liner 300 occupies the space used to form the bit line spacer. Therefore, by adjusting the material of the liner 300, the capacitance in the semiconductor device 1 may be adjusted correspondingly. For example, when the bit line spacer includes silicon oxide and the liner 300 includes silicon nitride, the liner 300 occupies a portion of the space used to form the bit line spacer. Therefore, the occupation amount of silicon oxide on the sidewall of the bit line structure is decreased (and the occupation amount of silicon nitride is increased), thereby reducing the capacitance in the semiconductor device 1.

As shown in FIG. 8, the upper width 220a of the trench 220 may be greater than the bottom width 220b of the trench 220 to facilitate conformal formation of the liner 300 in the trench 220. For example, the trench 220 may have a pentagonal profile, a bullet-shaped profile, or other similar profiles, thereby reducing the drop at the corners when the liner 300 is conformally formed. Thus, the reliability of the liner 300 may be improved.

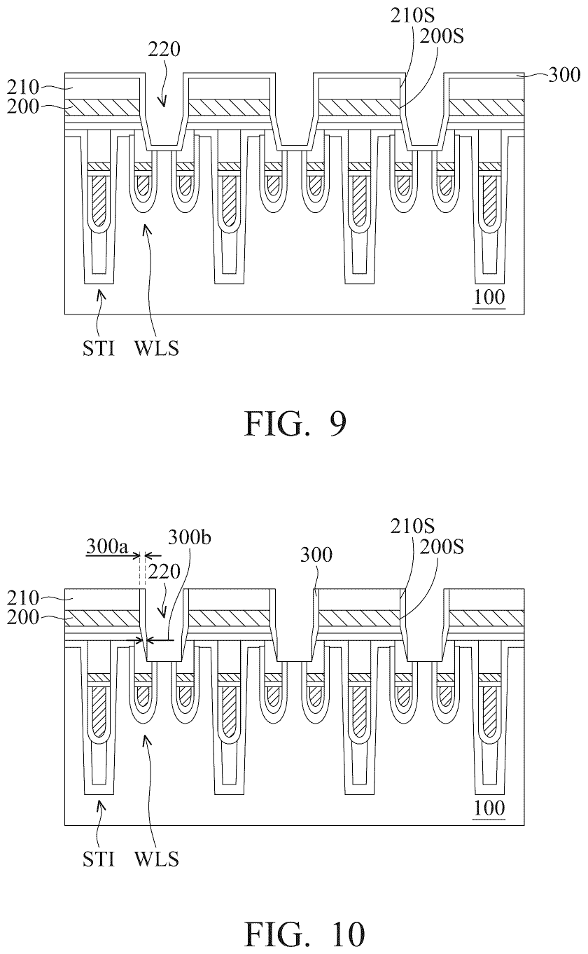

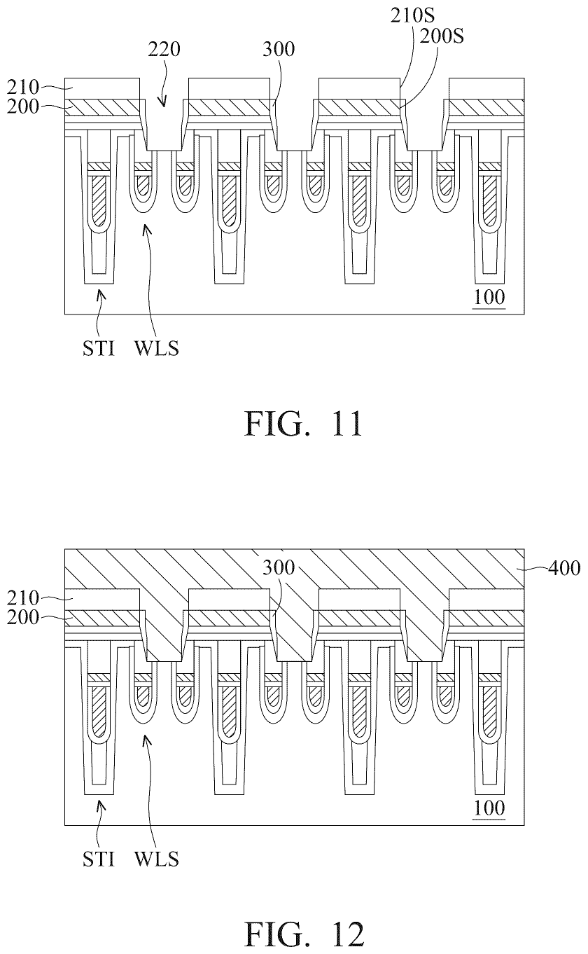

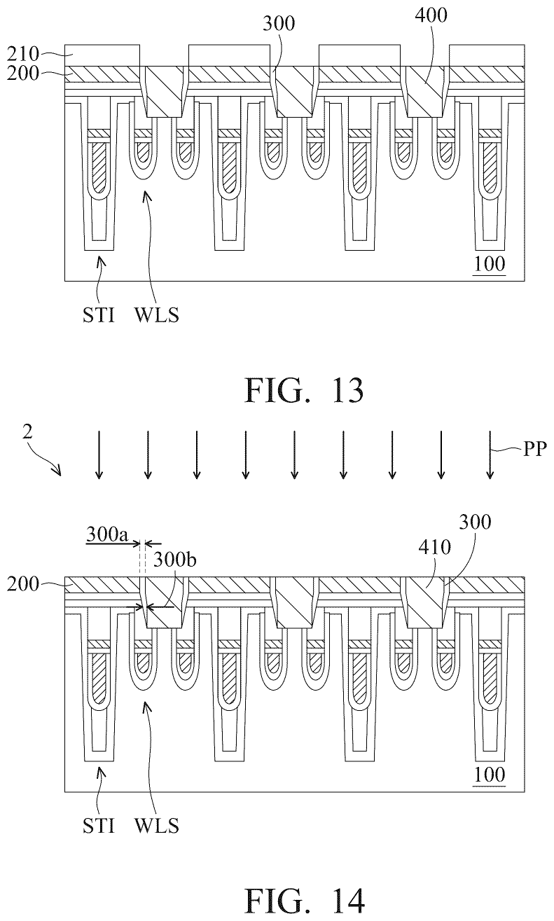

As shown in FIG. 9, the liner 300 is formed in the trench 220. As shown in FIG. 10, a portion of the liner 300 is removed to expose the top surface of the substrate 100. As shown in FIG. 11, the liner 300 is etched back to remove a vertical portion of the liner 300, the liner 300 is etched back without substantially removing the word line structure WLS and the substrate 100. As shown in FIG. 12, the contact material 400 is deposited in the trench 220 (refer to FIG. 11). As shown in FIG. 13, the contact material 400 is etched back so that the top surface of the contact material 400 is aligned with the top surface of the liner 300. As shown in FIG. 14, the planarization process PP is performed to make the top surface of the gate conductive layer 200, the top surface of the contact material 400 (refer to FIG. 13), and the top surface of the liner 300 coplanar, to form the contact 410 in the trench 220 (refer to FIG. 11). Thus, the semiconductor device 2 is obtained.

As shown in FIG. 15, continuing from FIG. 10, an ion implantation process IP is performed on the liner 300 to remove a portion of the upper portion 310 of the liner 300, the ion implantation process IP is performed by using helium (He) ions, neon (Ne) ions, argon (Ar) ions, krypton (Kr) ions, xenon (Xe) ions, or a combination thereof. The radioactive radon (Rn) ions are avoided. For example, xenon (Xe) ions with a relatively large atomic weight may be used to perform the ion implantation process IP to effectively remove a portion of the liner 300 to shape the liner 300.

After the ion implantation process IP is performed on the liner 300, the upper portion 310 of the liner 300 may have a curved (arc-shape) profile when viewed in a cross-sectional view, the curved profile of the upper portion 310 of the liner 300 on one sidewall of the trench 220 projects outwardly toward the opposite sidewall of the trench 220, the bottom portion 320 of the liner 300 may have a curved profile. After the ion implantation process IP is performed, the upper width 220a of the trench 220 may be widened. For example, the upper width 220a of the trench 220 may be greater than the bottom width 220b of the trench 220 to facilitate reducing the aspect ratio of trench 220 that is subsequently filled with contact material. Therefore, performing the ion implantation process IP avoids the creation of seams in the subsequently formed contacts. The step of etching back the liner 300 may be omitted, and a portion of the word line structure WLS and a portion of the substrate 100 are substantially not removed.

Performing the ion implantation process IP may remove residual portions of liner 300 that may be present on the bottom surface of trench 220. Therefore, performing the ion implantation process IP may improve the process adjustability of the removal process of removing the horizontal portion of the liner 300. In other words, since the ion implantation process IP may remove residual portions of liner 300 that may be present on the bottom surface of trench 220, even though residual portions of liner 300 is present on the bottom surface of trench 220, it also be removed by the ion implantation process IP.

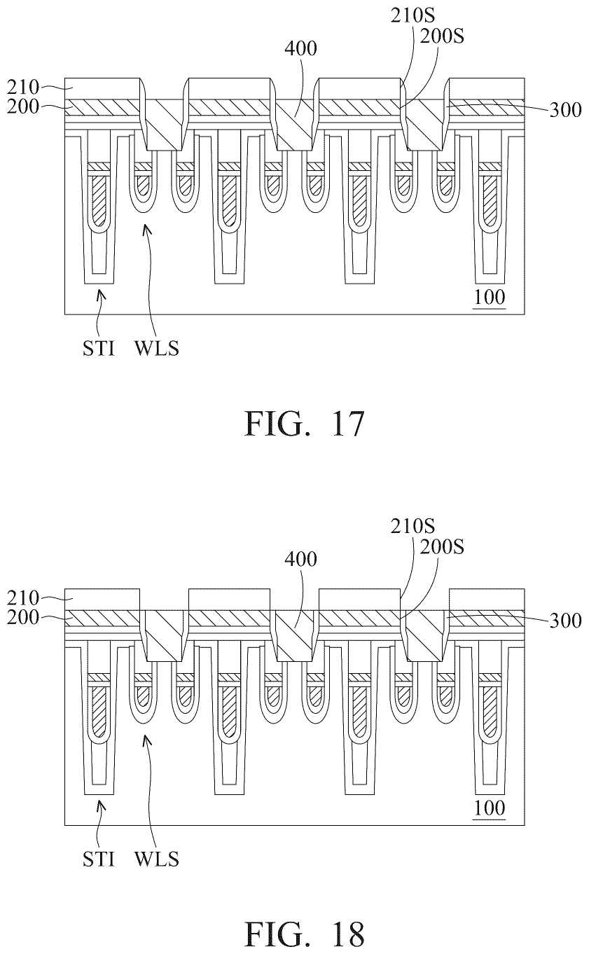

As shown in FIG. 16, the contact material 400 is deposited in the trench 220 (refer to FIG. 15). As shown in FIG. 17, the contact material 400 is etched back so that the top surface of the contact material 400 is aligned with the top surface of the liner 300. As shown in FIG. 18, a wet cleaning process is performed to remove the liner 300 covering the mask 210, so that the top surface of the liner 300 is aligned with the top surface of the gate conductive layer 200, the wet cleaning process may use a cleaning solution such as phosphoric acid. Accordingly, the process adjustability for subsequent planarization processes may be improved. For example, the planarization process is easier to perform and/or the flatness of the surface after the planarization process is increased.

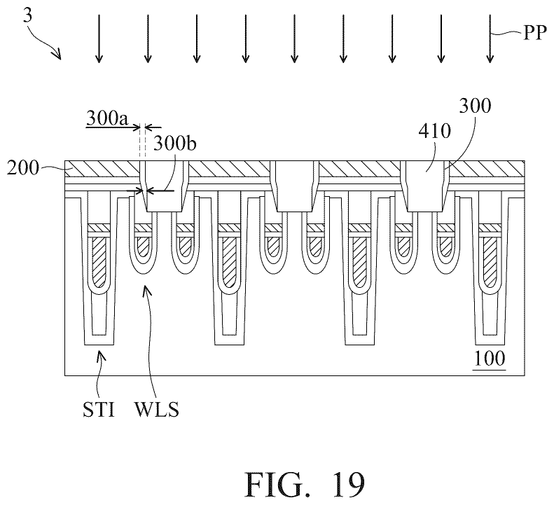

As shown in FIG. 19, the planarization process PP is performed to make the top surface of the gate conductive layer 200, the top surface of the contact material 400 (refer to FIG. 18), and the top surface of the liner 300 coplanar, to form the contact 410 in the trench 220 (refer to FIG. 15). Therefore, the semiconductor device 3 is obtained. As shown in FIG. 19, the upper width 300a of the liner 300 may be greater than the bottom width 300b of the liner 300. Since the liner 300 adjacent to the gate conductive layer 200 is thicker, the liner 300 may effectively separate the contact 410 and the gate conductive layer 200 from each other.

Accordingly, the semiconductor device and the method of forming the semiconductor device of the present disclosure may dispose the liner 300 between the gate conductive layer 200 and the contact 410, and make the liner 300 cover the side surface 200S of the gate conductive layer 200, so as to reduce the seams formed in the contacts 410 and/or reduce the capacitance in the semiconductor device to improve the electrical performance and reliability of the semiconductor device.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a word line structure disposed in the substrate;
a gate conductive layer disposed on the word line structure;
a contact disposed on the word line structure; and
a liner disposed between the gate conductive layer and the contact, and covering a side surface of the gate conductive layer.

2. The semiconductor device as claimed in claim 1, wherein a top surface of the gate conductive layer, a top surface of the contact, and a top surface of the liner are coplanar.

3. The semiconductor device as claimed in claim 1, wherein an upper width of the liner is greater than a bottom width of the liner.

4. The semiconductor device as claimed in claim 1, wherein the contact is in contact with the substrate.

5. The semiconductor device as claimed in claim 1, wherein an upper width of the contact is greater than a bottom width of the contact.

6. The semiconductor device as claimed in claim 1, wherein the word line structure comprises:
a first dielectric layer disposed in the substrate;
a word line conductive structure disposed on the first dielectric layer; and
a second dielectric layer disposed on the word line conductive layer, and wherein the first dielectric layer and the second dielectric layer surround the word line conductive structure,
wherein the liner is in contact with the second dielectric layer.

7. The semiconductor device as claimed in claim 6, wherein the contact is in contact with the first dielectric layer and the second dielectric layer of the word line structure.

8. The semiconductor device as claimed in claim 1, further comprising:
an isolation structure disposed in the substrate, and wherein the gate conductive layer is disposed on the isolation structure.

9. A method of forming a semiconductor device, comprising:
providing a substrate;
forming a word line structure in the substrate;
forming a gate conductive layer on the word line structure;
forming a trench in the gate conductive layer, the word line structure, and the substrate;
forming a liner in the trench, so that the liner covers a side surface of the gate conductive layer; and
forming a contact in the trench.

10. The method as claimed in claim 9, wherein the formation of the liner in the trench comprises:
conformally forming the liner in the trench; and
removing a portion of the liner to expose a top surface of the substrate.

11. The method as claimed in claim 10, wherein the formation of the liner in the trench further comprises:
etching back the liner, so that a top surface of the liner is higher than or aligned with a top surface of the gate conductive layer.

12. The method as claimed in claim 11, wherein the liner is etched back to remove a portion of the word line structure and a portion of the substrate, so that the trench extends toward the substrate.

13. The method according to claim 12, wherein after the removal of the portion of the word line structure and the portion of the substrate, an upper width of the trench is greater than a bottom width of the trench.

14. The method as claimed in claim 10, wherein the formation of the liner in the trench further comprises:
performing an ion implantation process on the liner to remove a portion of the liner, such that an upper width of the trench is greater than a bottom width of the trench.

15. The method as claimed in claim 14, wherein after performing the ion implantation process on the liner, an upper portion of the liner has a curved profile.

16. The method as claimed in claim 14, wherein after performing the ion implantation process on the liner, a bottom portion of the liner has a curved profile.

17. The method as claimed in claim 14, wherein the ion implantation process is performed by using helium (He) ions, neon (Ne) ions, argon (Ar) ions, krypton (Kr) ions, xenon (Xe) ions, or a combination thereof.

18. The method as claimed in claim 9, wherein the formation of the contact in the trench comprises:
depositing a contact material in the trench; and
performing a planarization process so that a top surface of the gate conductive layer, a top surface of the contact material, and a top surface of the liner are coplanar in order to form the contact.

19. The method as claimed in claim 18, wherein the formation of the contact in the trench further comprises:
etching back the contact material, so that the top surface of the contact material is aligned with the top surface of the liner.

20. The method as claimed in claim 9, wherein the trench is formed in the gate conductive layer, the word line structure, and the substrate, so that the trench penetrates the gate conductive layer to expose the side surface of the gate conductive layer, a top surface of the word line structure, and a top surface of the substrate.
